(19) United States
(12) Patent Application Publication
(10) Pub. No.: US 2024/0274755 A1
(43) Pub. Date: Aug. 15, 2024

(54) LIGHT EMITTING ELEMENT AND METHOD FOR MANUFACTURING THE SAME

(71) Applicant: TOYODA GOSEI CO., LTD., Kiyosu-shi (JP)

(72) Inventors: Shinichi MATSUI, Kiyosu-shi (JP); Hideki OMOYA, Kiyosu-shi (JP); Hiroaki MAKINO, Kiyosu-shi (JP); Koichi MIZUTANI, Kiyosu-shi (JP)

(21) Appl. No.: 18/416,183

(22) Filed: Jan. 18, 2024

(30) Foreign Application Priority Data
Feb. 15, 2023 (JP) 2023-021328

(51) Int. Cl. H01L 33/46; H01L 33/00; H01L 33/32

(52) U.S. Cl. CPC H01L 33/46; H01L 33/0075; H01L 33/32; H01L 2933/0025

(57) ABSTRACT

A light emitting element having an emission wavelength of 200 nm or more and 280 nm or less and including a group-III nitride semiconductor, which includes a substrate, an antireflection film provided on a backside of the substrate, a semiconductor layer including an n-type layer, a light emitting layer, and a p-type layer; a hole provided in a predetermined region of a surface of the p-type layer, a first p-electrode provided on the p-type layer, a first n-electrode provided on the n-type layer, a second p-electrode provided on the first p-electrode, a second n-electrode provided on the first n-electrode, and a protective film covering an entire upper surface of the element. The protective film includes: a first protective film made of an insulating material and a second protective film made of an insulating material having an internal stress other than that of the insulating material of the first protective film.

### CROSS-REFERENCE

This application claims priority to Japanese patent application No. 2023-021328 filed on Feb. 15, 2023, the contents of which are fully incorporated herein by reference.

### TECHNICAL FIELD

The present disclosure relates to a light emitting element and a method for manufacturing the same.

### BACKGROUND ART

In recent year, a lot of attention has been drawn to use of ultraviolet LEDs having an emission wavelength in a UVC wavelength region (200 to 280 nm) and including a group-III nitride semiconductor for sterilization/antisepsis of water, air, etc., and research and development of high-efficiency ultraviolet LED have been actively advanced.

It is problematic that UVC is easily absorbed inside an LED and thus a light extraction efficiency is poor. Therefore, an antireflection film is formed on the backside of a substrate to thereby increase a light extraction efficiency (see JP-A-2021-517736).

### SUMMARY

However, in the case where the antireflection film is formed on the backside of a substrate after a protective film has been formed, peel-off and/or cracks occur(s) on the protection film of the element due to a thermal load applied during formation of the antireflection film, which results in leak defect in some cases.

The present disclosure has been made in view of such a background, and an object of the disclosure is to provide a light emitting element a protection film of which is prevented from peeling and/or cracking and a method for manufacturing the same.

One aspect of the present disclosure is a light emitting element having an emission wavelength of 200 nm or more and 280 nm or less and including a group-III nitride semiconductor, the element comprising:
a substrate;
an antireflection film provided on a backside of the substrate;
a semiconductor layer including an n-type layer, a light emitting layer, and a p-type layer which are laminated on a surface of the substrate in this order;
a hole provided in a predetermined region of a surface of the p-type layer, the hole having a depth reaching the n-type layer;
a first p-electrode provided on the p-type layer in contact therewith;
a first n-electrode provided on the n-type layer exposed at a bottom of the hole;
a second p-electrode provided on the first p-electrode;
a second n-electrode provided on the first n-electrode; and
a protective film covering an entire upper surface of the element, the protective film comprising an insulating material, wherein
the protective film includes:
a first protective film made of the insulating material and
a second protective film formed on the first protective film, the second protective film being made of the insulating material having an internal stress other than that of the insulating material of the first protective film.

Another aspect of the present disclosure is a method of manufacturing a light emitting element having an emission wavelength of 200 nm or more and 280 nm or less and including a group-III nitride semiconductor, comprising the steps of:
forming a semiconductor layer by laminating an n-type layer, a light emitting layer, and a p-type layer on a surface of a substrate in this order;
forming a hole in a predetermined region of a surface of the p-type layer, the hole having a depth reaching the n-type layer;
forming a first p-electrode on the p-type layer;
forming a first n-electrode on the n-type layer exposed at a bottom of the hole;
forming a second p-electrode and a second n-electrode respectively on the first p-electrode and the first n-electrode;
forming a first protective film covering an entire upper surface of the element, the first protective film being made of an insulating material; and
forming a second protective film on the first protective film, the second protective film being made of the same material as the first protective film, wherein the first protective film and the second protective film are formed in a different way to have different internal stresses.

In the above-mentioned aspect, the protective film includes two layers which are different in internal stress, so that the internal stress of the protective film can be reduced to thereby prevent peeling and cracking of the protective film which would be caused by a thermal load during formation of the antireflection film.

### BRIEF DESCRIPTION OF THE DRAWINGS

FIG. 1 shows a cross section vertical to a principal surface of a substrate of a light emitting element according to an embodiment to illustrate the structure of the light emitting element.

FIG. 2 shows a planer pattern of an electrode of the light emitting element according to the embodiment.

FIG. 3 shows a step of manufacturing the light emitting element according to the embodiment.

FIG. 4 shows a step of manufacturing the light emitting element according to the embodiment.

FIG. 5 shows a step of manufacturing the light emitting element according to the embodiment.

FIG. 6 shows a step of manufacturing the light emitting element according to the embodiment.

FIG. 7 shows a step of manufacturing the light emitting element according to the embodiment.

FIG. 8 shows a step of manufacturing the light emitting element according to the embodiment.

FIG. 9 shows a step of manufacturing the light emitting element according to the embodiment.

FIG. 10 shows a step of manufacturing the light emitting element according to the embodiment.

FIG. 11 is a graph showing a relation between a heat dissipation area and AT.

### DETAILED DESCRIPTION OF THE EMBODIMENTS

A light emitting element has an emission wavelength of 200 nm or more and 280 nm and includes a group-III nitride semiconductor. The light emitting element comprises a substrate, an antireflection film provided on a backside of the substrate, a semiconductor layer including an n-type layer, a light emitting layer, and a p-type layer which are laminated on a surface of the substrate in this order, a hole provided in a predetermined region of a surface of the p-type layer, of which a depth reaching the n-type layer, a first p-electrode provided on the p-type layer in contact therewith, a first n-electrode provided on the n-type layer exposed at a bottom of the hole, a second p-electrode provided on the first p-electrode, a second n-electrode provided on the first n-electrode, a protective film which covers an entire upper surface of the element and is made of an insulating material. The protective film includes a first protective film which is made of the insulating material and a second protective film which is formed on the first protective film and is made of the insulating material having an internal stress other than that of the insulating material of the first protective film. Throughout the specification, the word “on” is used not only in the case of direct lamination (two objects are in contact with each other) but also in the case of indirect lamination (two objects have something interposed therebetween), unless otherwise noted.

The first protective film and the second protective film may be made of different material.

The first protective film may be made of SiO₂, and the second p-electrode and the second n-electrode may be respectively composed of a plurality of layers having an upmost layer formed of a Ta layer that is in contact with the first protective film. By this configuration, the protection film can be prevented from peeling during formation of the antireflection film.

The light emitting element may further comprise a reflection film between the first protective film and the second protective film, which is made of a material that reflects ultraviolet rays having the emission wavelength of the element. By this configuration, an insulation property of the protective film can be improved.

A method of manufacturing a light emitting element is a method of manufacturing a light emitting element having an emission wavelength of 200 nm or more and 280 nm or less and including a group-III nitride semiconductor. The method includes the steps of forming a semiconductor layer by laminating an n-type layer, a light emitting layer, and a p-type layer on a surface of a substrate in this order; forming a hole in a predetermined region of a surface of the p-type layer, the hole having a depth reaching the n-type layer; forming a first p-electrode on the p-type layer; forming a first n-electrode on the n-type layer exposed at a bottom of the hole; forming a second p-electrode and a second n-electrode respectively on the first p-electrode and the first n-electrode; forming a first protective film covering an entire upper surface of the element, the first protective film being made of an insulating material; and forming a second protective film on the first protective film, the second protective film being made of the same material as the first protective film, wherein the first protective film and the second protective film are formed in a different way to have different internal stresses.

The first protective film may be formed by CVD, and the second protective film may be formed by sputtering.

The method may further include the step of forming a reflection film made of a material that reflects ultraviolet rays having the emission wavelength of the element after the step of forming the first protective film and before the step of forming the second protective film.

### EMBODIMENT

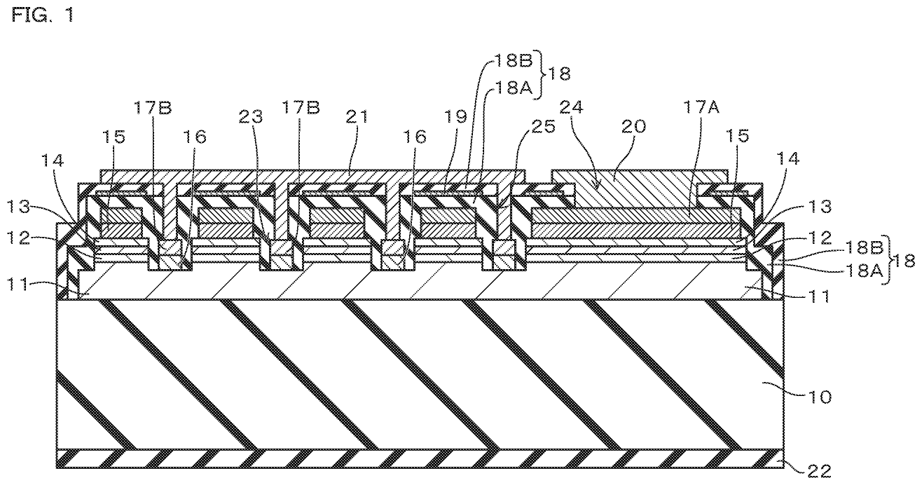

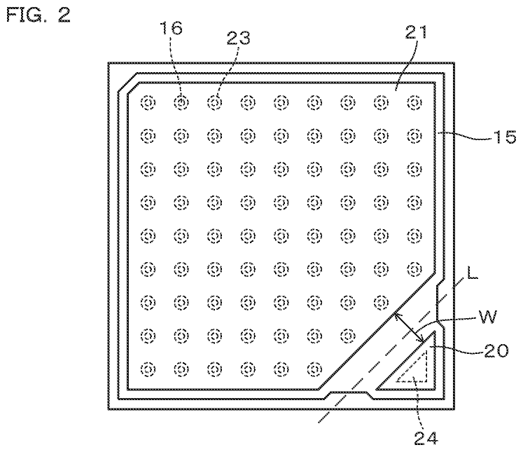

FIG. 1 shows a cross section vertical to a substrate of a light emitting element according to an embodiment to illustrate the structure of the light emitting element. FIG. 2 shows a planer pattern of an electrode of the light emitting element according to the embodiment. The light emitting element of the embodiment is a flip-chip ultraviolet light emitting element, the emission wavelength of which is in the UVC wavelength region and is, for example, 200 to 280 nm.

### 1. Components of the Light Emitting Element

FIG. 1 shows that the light emitting element according to the embodiment includes a substrate 10, a n-type layer 11, a light emitting layer 12, an electron block layer 13, a p-type layer 14, a first p-electrode 15, a first n-electrode 16, a second p-electrode 17A, a second n-electrode 17B, a protective film 18, a reflection film 19, a p-pad electrode 20, an n-pad electrode 21, and an antireflection film 22. An explanation of each component will be described below.

The substrate 10 is made of sapphire having a c-surface set as the principal surface. Any material other than sapphire, which has a high transmission and can grow a group-III nitride semiconductor, can be used for the substrate. A thickness of the substrate is, for example, 0.4 to 1 mm. By setting the thickness within this range, light extraction efficiency can be improved. However, the substrate having a large thickness tends to easily have a temperature therein, so that the heat dissipation property decreases, which causes reduction of the service life of the element. Therefore, in the embodiment, the electrode pattern is set in the manner described below to thereby improve the heat dissipation property.

A backside of the substrate 10 (the surface on the side opposite to the n-type layer 11 side, corresponding to a light extraction side) is provided with the antireflection film 22. The antireflection film 22 thus provided prevents ultraviolet rays from reflecting on the backside of the substrate 10 and returning to the element side to thereby improve light extraction performance.

The antireflection film 22 has a structure composed of a single layer or a laminated structure composed of plural layers in which materials different in refractive index are alternately laminated, and the thickness of each layer is set such that the film weakens reflected light using interference of the light. The material of the antireflection film 22 is an insulating material. The examples of the insulating material include SiO₂, HfO₂, MgF₂, and so on.

The n-type layer 11 is located on the substrate 10 through a buffer layer (not shown in the figure). The n-type layer 11 is made of n-AlGaN. An n-type impurity is Si, the concentration of which is in the range of 5×10¹⁸ to 5×10¹⁹/cm³. The n-type layer 11 may be multilayered.

The light emitting layer 12 is located on the n-type layer 11. The light emitting layer 12 has a MQW (Multiple Quantum Well) structure in which a well layer and a barrier layer are laminated in turn repeatedly. The number of repetition is, for example, 2 to 5. The well layer is made of AlGaN in which an Al composition is set as appropriate according to an intended emission wavelength. The barrier layer is made of AlGaN an Al composition of which is higher than that in the well layer. AlGaN having a band gap energy higher than that of the well layer may be employed. The light emitting layer 12 may have a SQW (Single Quantum Well) structure.

The electron block layer 13 is located on the light emitting layer 12. The electron block layer 13 is made of p-AlGaN having an Al composition higher than that in the barrier layer of the light emitting layer 12. The electron block layer 13 prevents electrons injected from the n-electrode 16 from passing through the light emitting layer 12 and diffusing into the p-type layer 14 side.

The p-type layer 14 is located on the electron block layer 13. The p-type layer 14 is made of p-AlGaN. In the light emitting element according to the embodiment, all of the n-type layer 11 through the p-type layer 14 as the semiconductor layer are made of AlGaN, and thus the semiconductor layer is prevented from absorbing ultraviolet light. The p-type layer 14 has an Al content of 5 to 80%, for example. Mg is contained as a p-type impurity. The concentration of Mg is 1×10¹⁹/cm³ or higher. The p-type layer 14 may be formed of a plurality of layers having different Al composition and Mg concentration from each other. In this case, the layer in contact with the p-electrode 15 only needs to be made of p-AlGaN of which the Al content is 5 to 80%. Besides, not only AlGaN but a group-III nitride semiconductor containing Al may be adopted for the p-type layer 14. AlGaInN may be adopted as well.

In a partial region on the surface of the p-type layer 14, holes 23 having a depth reaching the n-type layer 11 are formed. Arrangement of the holes 23 are dot-like, and specifically a plurality of the holes 23 are provided in the region, being arranged in a pattern of a lattice (see FIG. 2). However, the holes 23 are not formed in a region, which corresponds to the under side of the p-pad electrode 20 (one of corner portions in the rectangular pattern of the element). The n-type layer 11 is exposed at the bottom of the holes 23. The holes 23 for exposing the n-type layer 11 are arranged in a dot-like pattern so that reduction in light emission area (an area of the p-type layer 14) is lessened as much as possible while surely achieving uniformity of light emission on the surface to thereby improve light output.

A planer pattern of each hole 23 is, for example, circle. Other than circle, any polygon such as regular hexagon is also acceptable. In the case of regular hexagon, the side surface of the hole 23 is preferably a m-plane. The holes 23 are arranged in a pattern of a square lattice, a triangular lattice, or a honeycomb, for example.

The first p-electrode 15 is provided on the p-type layer 14. The first p-electrode 15 is provided in the region except end vicinal portions of the p-type layer 14 (see FIG. 2) to thereby ensure a broad light emission area. The first p-electrode 15 is a reflecting electrode by which ultraviolet rays emitted from the light emitting layer 12 is reflected to the substrate 10 side to thereby heighten light extraction efficiency. The first p-electrode 15 is made of a material having a low-contact resistance to the p-type layer 14 and having a high UVC reflectance. Examples of the material include Rh and Ru. Also a lamination of Ni or ITO with a reflecting layer is appropriate.

A ratio of the area of the first p-electrode 15 to the area of the upper surface of the element (a total area of the holes 23 and the p-type layer 14) is set to 70% or more. Planer patterns of the holes 23 and the first p-electrode 15 are determined to meet the abovementioned condition. For this purpose, for example, the diameter, number of arrays, and distance of arrays of the holes 23 are adjusted. By allowing the first p-electrode 15 to occupy a large area of the surface, reflection of ultraviolet rays by the first p-electrode 15 can be increased to thereby improve the light extraction efficiency. The ratio is preferably set to 75% or more.

The first n-electrodes 16 are provided on the n-type layer 11 exposed at the bottom of each hole 23. Therefore, the first n-electrodes 16 are also arranged in a dot-like pattern (see FIG. 2). The first n-electrodes 16 is constituted by a structure made of heat-treated V/Al/Ti. Also, Ti/Al/Ti etc. is applicable. The structure made of heat-treated V/Al/Ti is, specifically, structured by laminating a layer made of AlNₓ, a layer made of metal including Al as a main component, V, and Ti, and a layer made of Ti in sequence.

The layer made of of AlNₓ has a thickness of 1 to 3 nm. For example, a numerical value applied to a symbol x may be, for example, 0.4 to 0.7A. In this regard, x may decrease in number as the distance from the n-type layer 11 increases in the thickness direction. In this case, the average value of x in the thickness direction is 0.4 to 0.7. In some cases, Ga may diffuse from the n-type layer side. In such cases, the layer is made of Al_{y}Ga_{1-y}Nₓ (0.4≤x≤0.7) having a Al composition higher than that of the n-type layer 11. When defining the Al composition of the n-type layer 11 as a symbol a, the relational expression of a≤y≤1 is satisfied. The numerical value of y is, for example, 0.7 or more. Also in this case, x may decrease in number as the distance from the n-type layer 11 increases in the thickness direction, and y may increase in number as the distance from the n-type layer 11 increases in the thickness direction.

The layer made of a metal including Al as a main component, V, and Ti has a thickness of 50 to 500 nm. As for the ratio of Al, V, and Ti, for example, an Al content is 50 to 85 mol %, a V content is 5 to 20 mol %, and a Ti content is 10 to 30 mol %.

In the first n-electrode 16 having the above-mentioned structure, the contact resistance to the n-type layer 11 is reduced. For example, the contact resistivity of the first n-electrode 16 to the n-type layer 11 is 4×10⁻⁴ Ω·cm² or less. This is considered firstly because the layer of AlNₓ functions as a contact layer appropriate for the n-type layer 11. Secondly, this is considered because nitrogen vacancies are generated on the surface of the n-type layer 11, so that the surface of the n-type layer 11 becomes n-type, and thus the contact resistance decreases.

The layer made of Ti is provided as a cover to prevent Al contained in the n-electrode 16 from vaporizing at the time of alloying. Other than Ti, TiN, Ni, Pt, Au, etc., are applicable.

The second p-electrode 17A and the second n-electrode 17B are respectively provided on the first p-electrode 15 and the first n-electrode 16. A planer pattern of the second p-electrode 17A is the same as a planer pattern of the first p-type electrode 15. A planer pattern of the second n-electrode 17B is the same as a planer pattern of the first n-type electrode 16, and the pattern includes an arrangement of a plurality of dots.

The material of the second p-electrode 17A and the second n-electrode 17B is Ti/Ni/Au/Ta. Among a plurality of layers which forms the second p-electrode 17A and the second n-electrode 17B, an uppermost layer is in contact with the lower layer of the protective film 18 (a first protective film 18A). Ta has a thermal expansion coefficient close to that of SiO₂, and has high adhesion to SiO₂. Therefore, the uppermost layer formed of Ta enhances the adhesion between the second p-electrode 17A and the second n-electrode 17B and the protective film 18 and curtails peeling and/or cracking of the protective film 18 which would be caused by a thermal load during formation of the antireflection film 22.

The protective film 18 is provided over an entire upper surface of the element. In other words, the protective film 18 is provided continuously over the side surfaces, respectively, of the first p-electrode 15 and the first n-electrode 16, and the side and upper surfaces, respectively, of the second p-electrode 17A and the second n-electrode 17B, the side and upper surfaces of the semiconductor layer (the n-type layer 11, the light emitting layer 12, the electron block layer 13, and the p-type layer 14), the side surface of the element isolation trench 26, and the inside of holes 23.

The protective film 18 is structured to include two insulating materials different in internal stress (the first protective film 18A and the second protective film 18B) which are laminated in sequence. The above-mentioned internal stress means an internal stress that acts in the horizontal direction of the substrate 10. The different internal stresses may be compression stresses respectively having different magnitudes, tensile stresses respectively having different magnitudes, or compression and tensile stresses respectively having different magnitudes. Such a configuration can reduce the internal stress of the protective film 18 to thereby curtail peeling and/or cracking of the protective film 18 which would be caused by a thermal load during formation of the antireflection film 22.

In the embodiment, the protective film 18 is formed of a two-layered lamination including the first protective film 18A and the second protective film 18B. However, a three or more layered structure in which the first protective film 18A and the second protective film 18B are alternately laminated may also be used. Alternatively, three or more kinds of materials respectively having different internal stresses may also be used.

To make a difference in internal stress between the first protective film 18A and the second protective film 18B, a deposition method may be changed for the same material, or a deposition material may be changed in the same film forming method. In the case of using the same material, for example, SiO₂ may be deposited by sputtering or CVD. In this case, the internal stress in SiO₂ formed by sputtering can be made to be, for example, 110 MPa as a compression stress and the internal stress in SiO₂ formed by CVD can be made to be, for example, 500 MPa as a compression stress, so that the first protective film 18A and the second protective film 18B can form into two layers respectively having different internal stresses. Because it requires only to change the deposition method, the protective film 18 can be formed in a simple and easy manner.

If the protective film would be formed of a single layer deposited by sputtering, the internal stress can be made smaller in comparison with the two layered structure in which the protective film is deposited by sputtering and CVD. However, moisture permeates the protective film, and thus a problem occurs in use of the film under the environment of high humidity. When the protective film is formed in two-layered structure to avoid the problem, a moisture proof property of the protective film can be improved while reducing the internal stress therein.

Alternatively, in the case of using different materials, for example, SiO₂ may be used as the first protective film 18A and TiO₂ may be used as the second protective film 18B to make a difference in internal stress in the protective films. For the second protective film 18B, in addition to TiO₂, SiN, Al₂O₃, SiON, Nb₂O₅, etc., can be used. When the protective films are respectively made of different materials, the internal stress in the protective film 18 can be further reduced by choosing the material that generates a tensile stress and the material that generates a compression stress.

More specifically, SiO₂ that is deposited by sputtering can be given a compression stress of 110 MPa as an internal stress and TiO₂ that is deposited by sputtering can be given a compression stress of 547 Mpa as an internal stress or a tensile stress of 886 MPa of as an internal stress so as to make a difference in internal stress. Heat treatment largely changes the internal stress of TiO₂. Before the heat treatment, the internal stress is a compression stress, and after the heat treatment, the internal stress can be made to be a tensile stress.

The thickness ratio between the first protective film 18A and the second protective film 18B is preferably set so that the internal stress in an in-plane direction becomes as small as possible. Because the internal stresses in the first protective film 18A and the second protective film 18B are determined depending on the terms of respective thicknesses, depositing methods, deposition conditions, heating treatment after deposition, etc., of the films, the thicknesses of the first protective film 18A and the second protective film 18B are set according to these terms. In the case where one of the first protective film 18A and the second protective film 18B is a compression stress and another is a tensile stress, the internal stress of the protective film 18 can be set to be zero by adjusting the thickness ratio of the first protective film 18A and the second protective film 18B. The thickness ratio of the second protective film 18B to the first protective film 18A is set to, for example, 0.2 to 1.

The reflection film 19 made of Al is provided between the first protective film 18A and the second protective film 18B. The reflection film 19 is entirely provided there, except for the region where the after-mentioned holes 24 and 25 exist. The reflection film 19 reflects the light to the substrate 10 side to thereby improve light extraction efficiency. In addition, by embedding the reflection film 19 in the protective film 18, heat dissipation property of the protective film 18 is improved and migration of the reflection film 19 is prevented.

A material of the reflection film 19 is not limited to Al, and any material having a high reflectance in emission wavelength can be used. An alloy mainly composed of Al is applicable. The reflection film 19 may be provided inside the first protective film 18A and/or the second protective film 18B instead of providing between the first protective film 18A and the second protective film 18B. When providing a plurality of the reflection films 19, the planer pattern may be changed.

The p-pad electrode 20 and the n-pad electrode 21 are provided separately on the protective film 18. The p-pad electrode 20 is connected to the second p-electrode 17A through a hole 24 formed through the second protective film 18B. The n-pad electrode 21 is connected to the second n-electrode 17B through a hole formed through the second protective film 18B. A material for the p-pad electrode 20 and the n-pad electrode 21 is, for example, Ti/Pt/AuSn.

The planer patterns of the p-pad electrode 20 and the n-pad electrode 21 are as shown in FIG. 2. Specifically, a corner portion of a rectangular pattern positioned inside a rectangular pattern of the element is divided into two with a linear region having a width of W and being defined along a straight line L that has an angle of 45° with respect to the side of the rectangular pattern to separately form a pattern having a rectangular equilateral triangular shape, which serves as the p-pad electrode 20, and a pattern formed of the part other than the pattern of rectangular equilateral triangular shape, which has a shape of pentagon formed by cutting the corner of the rectangular and serves as the n-pad electrode 21. The first n-type electrode 16 are not located underneath the p-pad electrode 20, and all of the first n-type electrodes 16 are located underneath the n-pad electrode 21 and are connected to the n-pad electrode 21.

The angle of the linear region with respect to the side of the rectangular pattern is not limited to 45°, however, in order to lessen the area of the linear region and secure the sum of the areas of the p-pad electrode 20 and the n-pad electrode 21 as large as possible, the angle is preferably approximate to 45°, for example, preferably in the range of 30 to 60°, and more preferably in the range of 40 to 50°.

The position of the linear region and the width W are preferably set so that the sum of the areas of the p-pad electrode 20 and the n-pad electrode 21 occupies 90% or more of the light emission area (an area of the first p-electrode 15). As a matter of course, the width W is set so as not to cause short circuit between the p-pad electrode 20 and the n-pad electrode 21. For example, the width is set to 100 μm or more. In addition, the size of the p-pad electrode 20 is set so that the p-pad electrode 20 can be satisfactorily joined to the submount side. The electrode pattern of the submount is preferably in contact with the entire surface of the p-pad electrode 20 and the n-pad electrode 21. This is for the purpose of obtaining a large heat dissipation area (an area of the region where the p-pad electrode 20 and the n-pad electrode 21 are in contact with the electrode of the submount) to thereby enhance the heat dissipation property.

The planer patterns of the p-pad electrode 20 and the n-pad electrode 21 set as described above make it possible to largely obtain the sum of the areas of the p-pad electrode 20 and the n-pad electrode 21 to thereby obtain a large heat dissipation area, so that the heat dissipation property of the light emitting element can be enhanced. In particular, in a UVC light emitting element, the thickness of the substrate 10 is needed to be made larger for the purpose of improvement in light extraction efficiency, and thus the heat dissipation property is lowered. However, because the above-mentioned configuration makes it possible to improve the heat dissipation property, a satisfactory heat dissipation property can be reliably obtained even if a thick substrate is used.

As mentioned above, in the light emitting element according to the embodiment, the protective film 18 has a laminated structure including the first protective film 18A and the second protective film 18B respectively having different internal stresses. This configuration can reduce the stress of the protective film 18 and can prevent peeling and/or cracking of the protective film 18 which would be caused by a thermal load during formation of the antireflection film 22 on the backside of the substrate 10. In addition, because the uppermost layers of the second p-electrode 17A and the second n-electrode 17B is formed of Ta, the protective film 18 is prevented from being peeled and cracked by a thermal load during formation of the antireflection film 22.

### 2. Manufacturing Processes of the Light Emitting Element

The manufacturing processes of the light emitting element according to the embodiment will be described with reference to the figures.

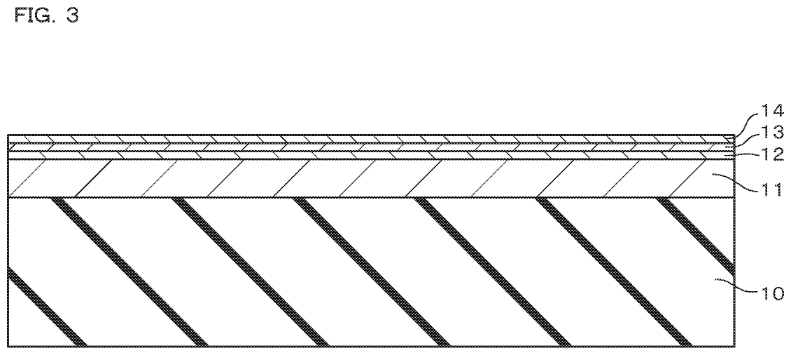

First, the substrate 10 made of sapphire is prepared. Then, the n-type layer 11, the light emitting layer 12, the electron block layer 13, and the p-type layer 14 are sequentially formed on the substrate 10 by the MOCVD method (see FIG. 3).

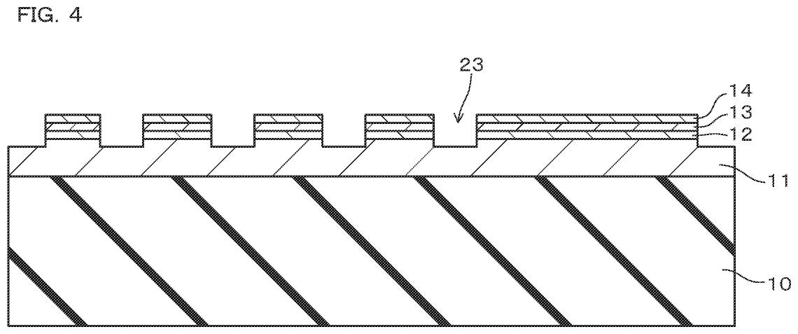

Then, a predetermined region of the p-type layer 14 is subjected to dry etching to form a plurality of the holes 23 each having a depth which reaches the n-type layer 11 (see FIG. 4).

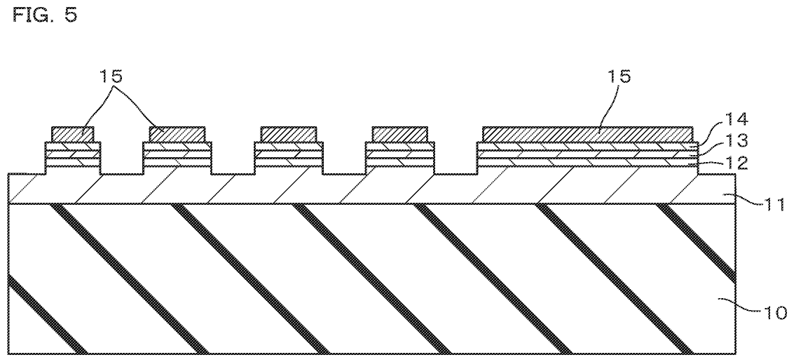

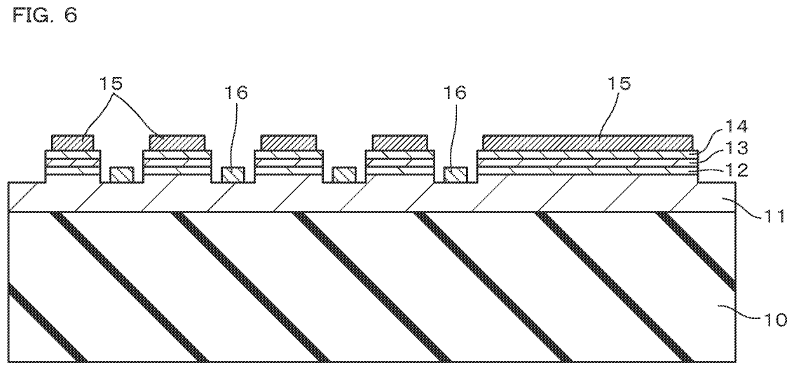

Then, the p-electrode 15 is formed on the p-type layer 14 by sputtering or vapor deposition (see FIG. 5). Then, a V layer, an Al layer, and a Ti layer are laminated in sequence by sputtering or vapor deposition on the n-type layer 11 that is exposed at the bottom of the holes 23 to thereby form the n-electrode 16 (see FIG. 6). The n-electrode 16 may be formed prior to the p-electrode 15 being formed. However, in order to form the p-electrode 15 under the condition where the surface of the p-type layer 14 is in a state as clean as possible, the p-electrode 15 is formed in first.

And then, heat treatment is performed at a temperature of 500 to 650° C. for 1 to 10 minutes. The atmosphere for performing the heat treatment is, for example, an atmosphere of an inert gas such as nitrogen. The heat treatment is preferably performed under reduced pressure, and the preferred pressure is in the range of, for example, 1×10² to 1×10⁴ Pa. The heat treatment temperature is preferably in the range of 500 to 600° C.

This heat treatment simultaneously performs an Mg activation treatment for the p-type layer 14 and reduction of contact resistances of the first p-electrode 15 and the first n-electrode 16.

In the embodiment, V/Al/Ti is used as the first n-electrode 16 to lower the heat treatment temperature and perform the Mg activation treatment for the p-type layer 14 and reduction of contact resistances of the first p-electrode 15 and the first n-electrode 16 in common at a time, so that the number of the heat treatment is reduced. Lowering of the heat treatment temperature and reduction of the number of the heat treatment result in prevention of deterioration in electric property of the light emitting element.

Here, the above-mentioned heat treatment changes the first n-electrode 16 structurally as mentioned below. V in V/Al/Ti which constitutes the first n-electrode 16 diffuses into Al but does not diffuse into the n-type layer 11 and Ti. As the result of this diffusion, the V layer disappears. Al in V/Al/Ti reacts with N in the n-type layer 11 to thereby form AlNₓ at the interface between the n-type layer 11 and the Al layer. In this regard, it is conceivable that V functions to accelerate the reaction between Al and N like catalyst. This heat treatment changes the structure of the first n-electrode 16 to a three-layer structure formed of a layer made of AlNₓ, a layer made of a metal including Al as a main component, V, and Ti, and a layer made of Ti.

Due to the structural change of the first n-electrode 16, the contact resistance of the first n-electrode 16 to the n-type layer 11 is reduced. The reason is as described before. That is, firstly, it is conceivable that the layer made of AlNₓ functions as an appropriate contact layer for the n-type layer 11. Secondly, it is conceivable that due to formation of AlNₓ, nitrogen vacancy generates on the surface of the n-type layer 11 whereby the n-type layer 11 more acceleratedly becomes n-type.

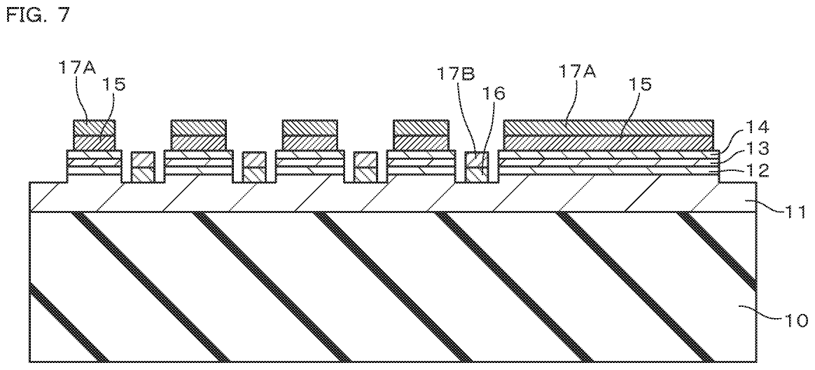

Next, the second p-electrode 17A and the second n-electrode 17B are formed respectively on the first p-electrode 15 and the first n-electrode 16 by sputtering or vapor deposition (see FIG. 7). The second p-electrode 17A and the second n-electrode 17B are multi-layered, and the uppermost layer is a Ta layer.

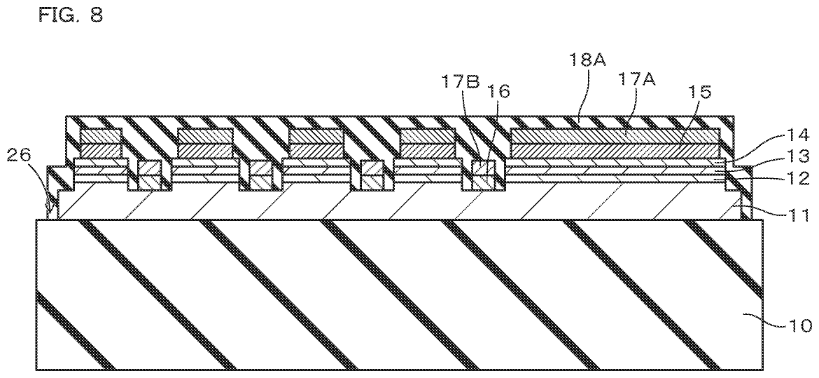

Then, the element isolation trench 26 is formed. The element isolation trench 26 has a depth sufficient for the substrate 10 being exposed. Then, the first protective film 18A which covers an entire upper surface of the element and is made of SiO₂ is formed (see FIG. 8). The first protective film 18A is deposited by CVD, sputtering, vapor deposition, ALD, etc. From the viewpoint of denseness of the film, sputtering, CVD, and ALD are preferred.

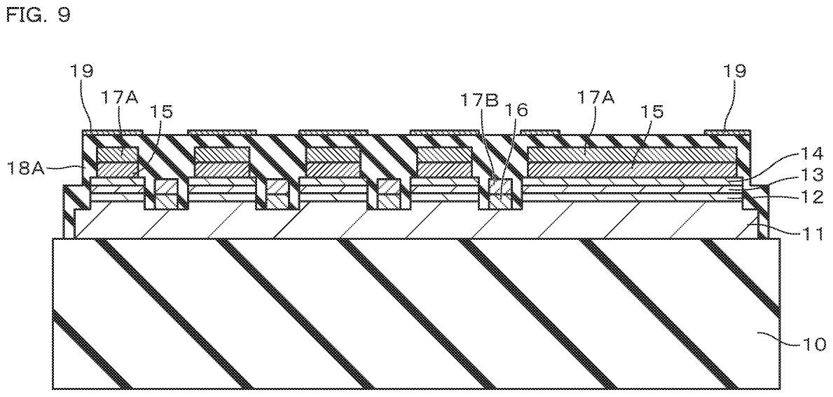

Then, the reflection film 19 made of Al is formed in a region on the first protective film 18A except a region in which the holes 24 and 25 will be formed (see FIG. 9). Deposition of the reflection film 19 is performed by vapor deposition or sputtering, and patterning is performed by wet etching.

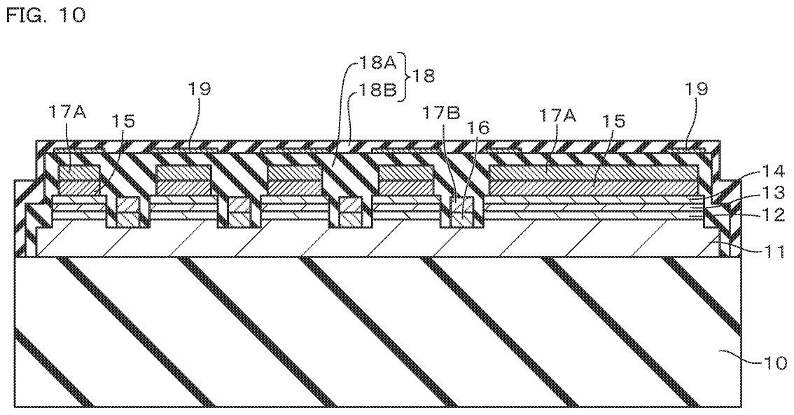

Then, on the first protective film 18A and the reflection film 19, the second protective film 18B is formed. The second protective film 18B is deposited by CVD, sputtering, vapor deposition, ALD, etc. From the viewpoint of denseness of the film, sputtering, CVD, and ALD are preferred. In this way, the protective film 18 including the first protective film 18A and the second protective film 18B which are laminated in this order is formed (see FIG. 10).

The internal stress of the second protective film 18B is made different from that of the first protective film 18B. Specifically, two protective films are deposited in a different way using the same material, or two protective films are formed of different materials. In the case of using the same material, for example, the first protective film 18A is made of SiO₂ formed by CVD, and the second protective film 18B is made of SiO₂ formed by sputtering. In the case of using different materials, for example, the first protective film 18A is made of SiO₂ and the second protective film 18B is made of TiO₂. In this way, the internal stresses of the first protective film 18A and the second protective film 18B are made different from each other, so that the internal stress of a whole of the protective film 18 can be reduced.

It is noted that the protective film 18 is preferably not formed at the bottom of the element isolation trench 26 and is preferably separated per element. This is to prevent pressure being applied on the protective film 18 and to prevent fluctuation being caused in the internal stress of the protective film 18 when dividing the protective film 18 per element.

Then, dry etching is performed on the predetermined region of the protective film 18 to thereby form the hole 24 and the hole 25 that reach the second p-electrode 17A and the second n-electrode 17B. Subsequently, the p-pad electrode 20 and the n-pad electrode 21 are respectively formed on the protective film 18 such that the p-pad electrode 20 is connected to the second p-electrode 17A through the hole 24 and the n-pad electrode 21 is connected to the second n-electrode 17B through the hole 25. The patterns of the p-pad electrode 20 and the n-pad electrode 21 are as shown in FIG. 2. The p-pad electrode 20 and the n-pad electrode 21 are deposited by vapor deposition or sputtering and are patterned by lift-off.

Then, the backside of the substrate 10 is polished to thereby reduce the thickness of the substrate 10 as predetermined, and subsequently the antireflection film 22 is formed on the backside of the substrate 10. When forming the antireflection film 22, a thermal load of 200 to 250° C. is applied for 2 to 3 hours. In the past when the protective film 18 was formed of a single layer made of SiO₂, heat stress was applied to the protective film 18 during formation of the antireflection film 22, and thus, the protective film 18 was peeled and cracked. In the light emitting element according to the embodiment, however, because the protective film 18 has a laminated structure including the first protective film 18A and the second protective film 18B respectively having different internal stresses, the internal stress of the protective film 18 is reduced to thereby prevent peeling and/or cracking of the protective film 18 which would be caused by a thermal load during formation of the antireflection film 22.

Then, the substrate 10 is divided into individual elements. In this way, the light emitting element according to the embodiment shown in FIG. 1 is manufactured.

### 3. Experimental Result

Each experimental result in the embodiment will be described below.

### (Experiment 1)

On a substrate made of sapphire, SiO₂ was deposited, and the internal stress of thus deposited SiO₂ was measured. The internal stress is an internal stress that acts in the horizontal direction of the substrate. When SiO₂ was deposited by CVD, a compression stress of 500 MPa generated in SiO₂. In the meantime, when SiO₂ was deposited by sputtering, a compression stress of 110 MPa generated in SiO₂. It was consequently found that a compression stress in the same material would be different if the material would be deposited in the different way.

### (Experiment 2)

The protective film 18 of the light emitting element according to the embodiment was formed as follows, and a plurality of light emitting elements was prepared. The protective film 18 was structured to have a three-layer lamination including SiO₂ deposited by CVD, SiO₂ deposited by sputtering, and SiO₂ deposited by CVD, each layer having a thickness of 320 nm. Each light emitting element was heated at 550° C. for four minutes. Then, a reverse current of each light emitting element was measured. As the result, the reverse current of all the light emitting elements was 0.1 μm or less, and no leak defect was found in all the light emitting elements.

### (Experiment 3)

The protective film 18 of the light emitting element according to the embodiment was formed as follows, and a plurality of light emitting elements was prepared. The protective film 18 was structured to have a five-layer lamination including SiO₂ deposited by CVD and SiO₂ deposited by sputtering that are alternately laminated, in which layers at both ends were formed by CVD and all the layers have a thickness of 320 nm. Then, each light emitting element was heated and a reverse current of the element was measured in the same manner as in Experiment 2. As the result, the reverse current of all the light emitting elements was 0.1 μm or less, and no leak defect was found in all the light emitting elements.

### (Experiment 4)

The protective film 18 of the light emitting element according to the embodiment was formed of a single layer having a thickness of 1 μm and made of SiO₂ deposited by CVD, and a plurality of the light emitting elements was prepared. Then, each light emitting element was heated and a reverse current of the element was measured in the same manner as in Experiment 2. As the result, the light emitting element having leak defect that was caused by the reverse current exceeding 0.1 μm was found.

From the results of Experiments 1 through 4, it was found that the configuration, in which the protective film 18 is structured to include a plurality of layers respectively having different internal stresses, can reduce the internal stress of the protective film 18, so that peeling and cracking of the protective film 18 which would be caused by a thermal load during formation of the antireflection film 22 can be prevented.

### (Experiment 5)

Electrode patterns of a light emitting element and a submount were variously changed to vary a heat dissipation area for the purpose of evaluating heat dissipation property. The heat dissipation property was evaluated in the following manner. A light emitting element was mount on a submount made of AlN, and the submount was arranged on a mounting substrate. The temperature on the surface of the light emitting element on the submount side was expressed as Tj, the temperature on the surface of the mounting substrate on the light emitting element side was expressed as Ts, and the difference between Tj and Ts was expressed as ΔT. Evaluation was performed on the basis of ΔT. It can be said that the less ΔT is, the higher the heat dissipation property is.

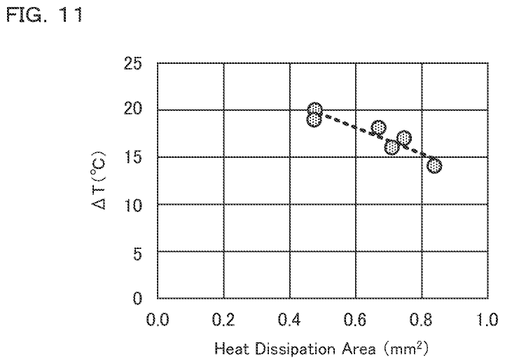

FIG. 11 is a graph showing a relation between a heat dissipation area and ΔT. As shown in FIG. 11, a linear relationship can be found in the heat dissipation area and ΔT. Specifically, it was found that as the heat dissipation area increases, ΔT decreases. It is apparent when the heat dissipation area increased by 0.4 mm², ΔT decreased by 5° C. Consequently, it was found that the heat dissipation property can be enhanced with a large heat dissipation area obtained by the electrode pattern of the light emitting element according to the embodiment.

### (Experiment 6)

A light emitting element according to the embodiment and a light emitting element not including the reflection film 19 provided to the light emitting element according the embodiment were prepared to evaluate heat dissipation property. The heat dissipation property was evaluated in the same manner as in Example 5. The heat dissipation area was set to 0.84 mm².

As the result of the measurement of ΔT, in the light emitting element including the reflection film 19 in the protective film 18, ΔT was 15° C. On the other hand, in the light emitting element not including the reflection film 19, ΔT was 17° C. From the fact that when the reflection film 19 was provided in the protective film 18, ΔT decreased by 2° C., increase in heat dissipation property becomes apparent.

What is claimed is:

1. A light emitting element having an emission wavelength of 200 nm or more and 280 nm or less and including a group-III nitride semiconductor, the element comprising:
a substrate;
an antireflection film provided on a backside of the substrate;
a semiconductor layer including an n-type layer, a light emitting layer, and a p-type layer which are laminated on a surface of the substrate in this order;
a hole provided in a predetermined region of a surface of the p-type layer, the hole having a depth reaching the n-type layer;
a first p-electrode provided on the p-type layer in contact therewith;
a first n-electrode provided on the n-type layer exposed at a bottom of the hole;
a second p-electrode provided on the first p-electrode;
a second n-electrode provided on the first n-electrode; and
a protective film covering an entire upper surface of the element, the protective film being made of an insulating material, wherein
the protective film includes:
a first protective film made of the insulating material and
a second protective film formed on the first protective film, the second protective film being made of the insulating material having an internal stress other than that of the insulating material of the first protective film.

2. The light emitting element according to claim 1, wherein the first protective film and the second protective film are made of different material.

3. The light emitting element according to claim 2, wherein the first protective film is made of SiO₂, and the second p-electrode and the second n-electrode are respectively composed of a plurality of layers having an upmost layer formed of a Ta layer that is in contact with the first protective film.

4. The light emitting element according to claim 1, further comprising a reflection film between the first protective film and the second protective film, the reflection film being made of a material that reflects ultraviolet rays having the emission wavelength of the element.

5. A method of manufacturing a light emitting element having an emission wavelength of 200 nm or more and 280 nm or less and including a group-III nitride semiconductor, comprising the steps of:
forming a semiconductor layer by laminating an n-type layer, a light emitting layer, and a p-type layer on a surface of a substrate in this order;
forming a hole in a predetermined region of a surface of the p-type layer, the hole having a depth reaching the n-type layer;
forming a first p-electrode on the p-type layer;
forming a first n-electrode on the n-type layer exposed at a bottom of the hole;
forming a second p-electrode and a second n-electrode respectively on the first p-electrode and the first n-electrode;
forming a first protective film covering an entire upper surface of the element, the first protective film being made of an insulating material; and
forming a second protective film on the first protective film, the second protective film being made of the same material as the first protective film, wherein
the first protective film and the second protective film are formed in a different way to have different internal stresses.

6. The method according to claim 5, wherein the first protective film is formed by CVD, and the second protective film is formed by sputtering.

7. The method according to claim 5, further comprising the step of forming a reflection film made of a material that reflects ultraviolet rays having the emission wavelength of the element after the step of forming the first protective film and before the step of forming the second protective film.
